(19) United States
(12) Patent Application Publication
(10) Pub. No.: US 2023/0314948 A1
(43) Pub. Date: Oct. 5, 2023

(54) NOZZLE HAVING DOUBLE PIPE STRUCTURE, AND PHOTORESIST DISPENSER AND SPIN COATER, EACH INCLUDING THE NOZZLE

(71) Applicant: SEMES CO., LTD.

(72) Inventors: Youngjun Son, Cheonan-si (KR); Byoungdoo Choi, Cheonan-si (KR)

(73) Assignee: SEMES CO., LTD., Cheonan-si (KR)

(21) Appl. No.: 18/108,655

(22) Filed: Feb. 12, 2023

(30) Foreign Application Priority Data
Mar. 30, 2022 (KR) 10-2022-0039868

(51) Int. Cl. G03F 7/16

(52) U.S. Cl. CPC G03F 7/162

(57) ABSTRACT

Provided are a nozzle having a double pipe structure in which multi-suck-back is possible without driving a nozzle arm, and also, a reduced resist consumption (RRC) operation and a nozzle tip rinsing operation are possible without moving the nozzle arm, and a photoresist (PR) dispenser and a spin coater, each including the nozzle. The nozzle includes an inner pipe having a conical shape gradually narrowing downward, through which PR is transferred, and having a tip through which the PR is ejected, and an outer pipe surrounding the inner pipe, having a conical shape gradually narrowing downward, through which thinner is transferred, and having a tip through which the thinner is ejected, wherein the nozzle is coupled to a nozzle arm and moved, and multi-suck-back is performed without driving the nozzle arm.

### CROSS-REFERENCE TO RELATED APPLICATION

This application claims the benefit of Korean Patent Application No. 10-2022-0039868, filed on Mar. 30, 2022, in the Korean Intellectual Property Office, the disclosure of which is incorporated herein in its entirety by reference.

### BACKGROUND

### 1. Field

The disclosure relates to a semiconductor device manufacturing apparatus, and more particularly, to a spin coater for coating a wafer with a photoresist.

### 2. Description of the Related Art

Semiconductor devices may be manufactured through a plurality of semiconductor processes. For example, the semiconductor processes may include a thin film deposition process, a photolithography process, an etching process, a cleaning process, an ion injection process, and the like. Among them, the photolithography process is a process of forming a photoresist (PR) pattern on a substrate such as a wafer. The photolithography process may include, for example, a PR coating process, a baking process, an exposure process, a developing process, and the like.

### SUMMARY

Provided is a nozzle having a double pipe structure, by which multi-suck-back is possible without driving a nozzle arm, and also, a reduced resist consumption (RRC) operation and a nozzle tip rinsing operation are possible without moving the nozzle arm, and a photoresist (PR) dispenser and a spin coater, each including the nozzle.

Furthermore, the technical objectives to be achieved by the disclosure are not limited to the above-described objectives, and other technical objectives that are not mentioned herein would be clearly understood by a person skilled in the art from the description of the disclosure.

Additional aspects will be set forth in part in the description which follows and, in part, will be apparent from the description, or may be learned by practice of the presented embodiments.

According to an aspect of the disclosure, a nozzle having a double pipe structure includes an inner pipe having a conical shape gradually narrowing downward, through which PR is transferred, and having a tip through which the PR is ejected, and an outer pipe surrounding the inner pipe, having a conical shape gradually narrowing downward, through which thinner is transferred, and having a tip through which the thinner is ejected, wherein the nozzle is coupled to a nozzle arm and moved, and multi-suck-back is performed without driving the nozzle arm.

In an embodiment, the tip of the inner pipe may protrude downward from the tip of the outer pipe, or the tip of the outer pipe may protrude downward from the tip of the inner pipe.

In an embodiment, an antistatic conductive layer is disposed on the outer pipe, and the conductive layer may be connected to ground.

In an embodiment, air, thinner, air, and PR may be sequentially disposed upward in the inner pipe through the multi-suck-back, and air and thinner may be sequentially disposed upward in the outer pipe.

In an embodiment, without moving the nozzle, an operation of rinsing a tip of the inner pipe may be automatically performed through an operation of ejecting the thinner from the outer pipe.

In an embodiment, an RRC operation, in which the thinner is ejected onto a wafer and spread and then the PR is ejected and spread, may be performed by using the nozzle, without moving the nozzle.

According to another aspect of the disclosure, a PR dispenser including a nozzle having a double pipe structure, and a nozzle arm moving the nozzle, wherein the nozzle includes an inner pipe having a conical shape gradually narrowing downward, through which PR is transferred, and having a tip through which the PR is ejected, and an outer pipe surrounding the inner pipe, having a conical shape gradually narrowing downward, through which thinner is transferred, and having a tip through which the thinner is ejected, and wherein multi-suck-back is performed in the nozzle without driving the nozzle arm.

In an embodiment, the tip of the inner pipe may protrude downward from the tip of the outer pipe, or the tip of the outer pipe may protrude downward from the tip of the inner pipe.

In an embodiment, an antistatic conductive layer may be disposed on the outer pipe, and the conductive layer may be connected to ground.

In an embodiment, there may be no movement of the nozzle in an RRC operation and an operation of rinsing a tip of the nozzle.

In an embodiment, the nozzle arm may include a nozzle block to which at least one nozzle is coupled, and a pipe block to which the nozzle block is coupled, and in which intermediate pipes through which the PR and the thinner are transferred to the nozzle are disposed.

According to another aspect of the disclosure, a spin coater includes a nozzle having a double pipe structure, a nozzle arm moving the nozzle, a transfer device moving the nozzle arm in one direction, and at least one spinner on which a wafer subject to coating is disposed, the at least one spinner rotating the wafer, wherein the nozzle includes: an inner pipe having a conical shape gradually narrowing downward, through which PR is transferred, and having a tip through which the PR is ejected, and an outer pipe surrounding the inner pipe, having a conical shape gradually narrowing downward, through which thinner is transferred, and having a tip through which the thinner is ejected, and wherein multi-suck-back is performed in the nozzle without driving the nozzle arm.

In an embodiment, the tip of the inner pipe may protrude downward from the tip of the outer pipe, or the tip of the outer pipe may protrude downward from the tip of the inner pipe.

In an embodiment, an antistatic conductive layer may be disposed on the outer pipe, and the conductive layer may be connected to ground.

In an embodiment, there may be no movement of the nozzle in an RRC operation and an operation of rinsing a tip of the nozzle.

In an embodiment, the spinner may include a plurality of spinners, the nozzle arm is moved to the spinner corresponding thereto through the transfer device, and PR coating is performed on the wafer corresponding thereto through an RRC operation without moving the nozzle.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic plan view of a spin coater according to an embodiment;

FIG. 2 is a perspective view of a PR dispenser of the spin coater of FIG. 1;

FIGS. 3A and 3B are a perspective view and a side view, respectively, showing a nozzle housing of the spin coater of FIG. 1, and a nozzle arm and a nozzle of the PR dispenser of FIG. 2;

FIGS. 4A and 4B are a perspective view and a cross-sectional view, respectively, showing the nozzle of the PR dispenser of FIG. 2;

FIGS. 5A and 6A, and FIGS. 5B and 6B are a perspective views and a cross-sectional views, respectively, showing the nozzle of the PR dispenser of FIG. 2, according to some other embodiments;

FIGS. 7A to 7D are conceptual views showing a multi-suck-back operation using the nozzle 100a of FIG. 5A;

FIGS. 8A and 8B are conceptual views showing a tip rinsing operation in the nozzle 100a of FIG. 5A;

FIGS. 9A to 9E are conceptual views showing a process of coating PR by using the spin coater of FIG. 1;

FIGS. 10A to 10D are conceptual views showing a reduced resist consumption (RRC) operation using the nozzle 100a of FIG. 5A in the process of coating PR using the spin coater of FIG. 1; and

FIGS. 11A and 12A, and FIGS. 11B and 12B are a perspective views and a cross-sectional views, respectively, showing the nozzle employed in the PR dispenser of FIG. 2, according to some other embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. Expressions such as “at least one of,” when preceding a list of elements, modify the entire list of elements and do not modify the individual elements of the list.

In the following description, embodiments of the disclosure are described in detail with reference to the accompanying drawings. The disclosure may, however, be embodied in many different forms and should not be construed as being limited to the embodiments set forth herein; rather, these embodiments are provided so that this disclosure will be thorough and complete, and will fully convey the concept of the disclosure to those of ordinary skill in the art.

In the following description, when an element is described to be connected to another element, the element may be connected directly to the other element or a third element may be interposed therebetween. Similarly, when an element is described to exist on another element, the element may exist directly on the other element or a third element may be interposed therebetween. Also, the structure or size of each element illustrated in the drawings may be exaggerated for convenience of explanation and clarity. In the drawings, a part that is not related to a description is omitted to clearly describe the disclosure. In the description with reference to the drawings, like constituents are indicated by like reference numerals, and redundant descriptions thereof are omitted Meanwhile, the terminologies used herein should be considered in descriptive sense only and not for purposes of limitation set forth in the claims.

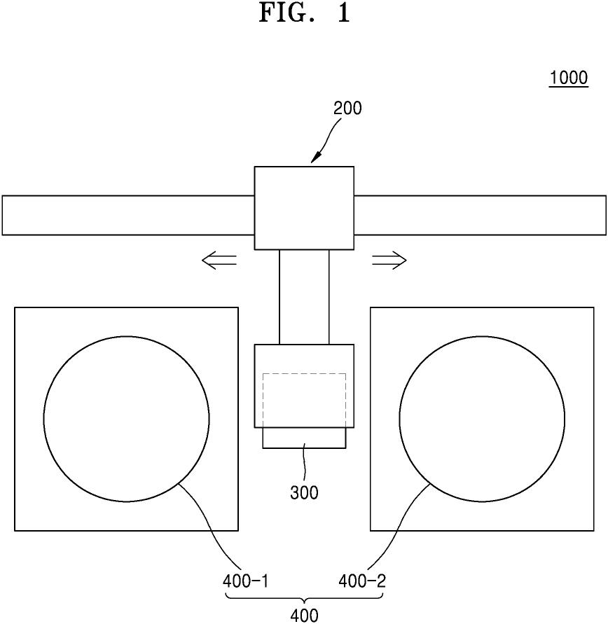

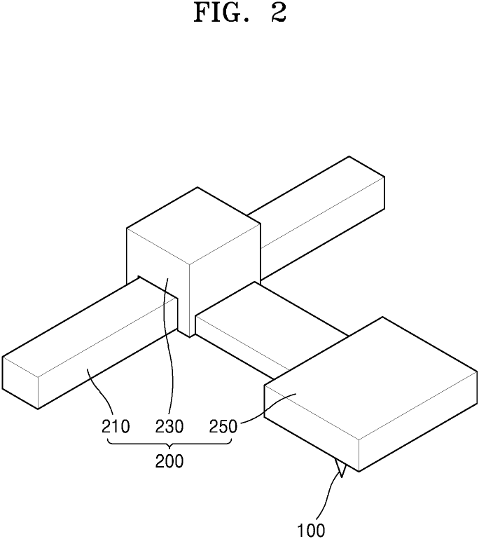

FIG. 1 is a schematic plan view of a spin coater 1000 according to an embodiment, and FIG. 2 is a perspective view of a PR dispenser 200 in the spin coater of FIG. 1.

Referring to FIGS. 1 and 2, the spin coater 1000 of the present embodiment may include a photoresist (PR) dispenser 200, a nozzle housing 300, and a spin-chuck 400. Furthermore, the spin coater 1000 may further include a photoresist (PR) supply unit, a purge gas supply unit, a thinner or organic solvent supply unit, and the like.

The PR dispenser 200 may include a moving rail 210, a moving body 230, a nozzle arm 250, and a nozzle 100. As indicated by arrows, the moving body 230 that is coupled to the moving rail 210 may move in a direction in which the moving rail 210 extends. The nozzle arm 250 may be coupled to the moving body 230. As the moving body 230 moves along the moving rail 210, the nozzle arm 250 may move to a position of the spin-chuck 400 corresponding thereto.

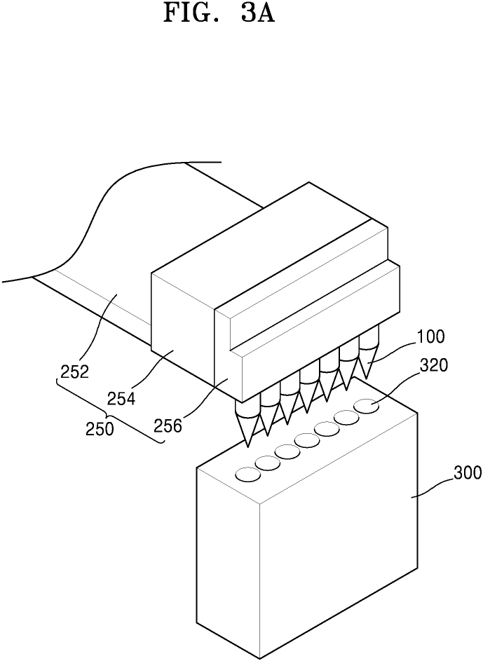

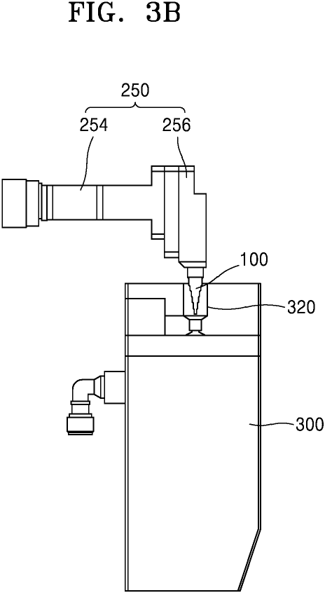

A plurality of nozzles 100 may be coupled to the nozzle arm 250. In detail, the nozzle arm 250 may include a support block (see 252 of FIG. 3A), a pipe block (see 254 of FIG. 3A), and a nozzle block (see 256 of FIG. 3A). The support block 252 may support a pipe block 254 and a nozzle block 256, and couple the nozzle arm 250 to the moving body 230. Intermediate pipes for transferring PR, thinner, constant temperature water, and the like may be disposed in the pipe block 254. The nozzle block 256 may be coupled to an end portion of the pipe block 254. The nozzles 100 may be coupled to the nozzle block 256.

The nozzle housing 300 may be disposed between two spin chucks 400-1 and 400-2. According to an embodiment, the nozzle housing 300 may be disposed on one side surface of any one spin chuck 400-1 or 400-2. The nozzle housing 300 may include a plurality of home spots 320 and accommodate a plurality of the nozzles 100 in the corresponding home spots 320. During idle time, the nozzle arm 250 may move the nozzles 100 to the home spots 320 of the nozzle housing 300.

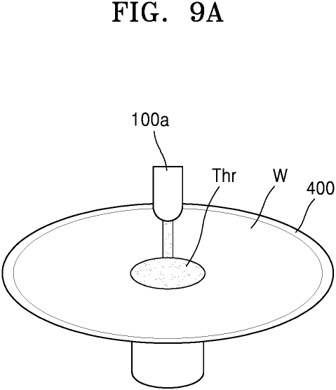

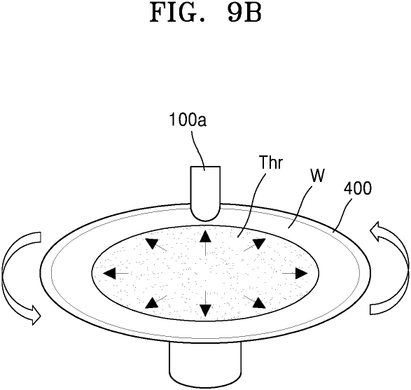

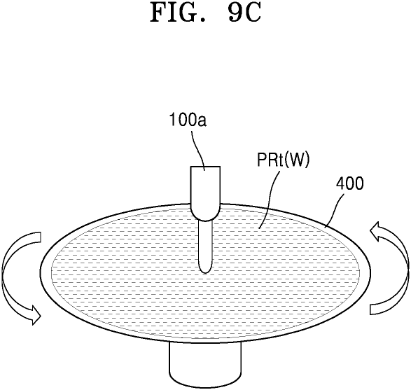

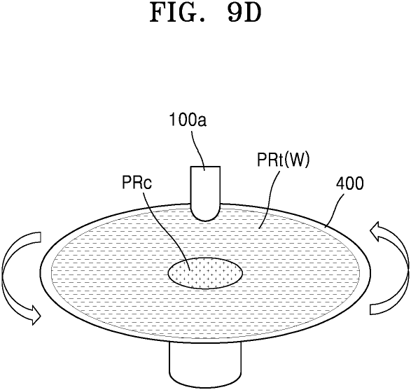

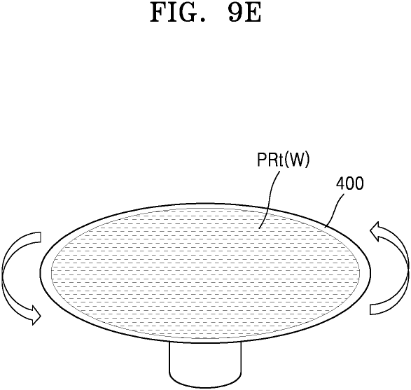

The spin-chuck 400 may include a first spin chuck 400-1 and a second spin chuck 400-2. According to an embodiment, the spin coater 1000 may include one spin chuck or three or more spin chucks. A wafer (see W of FIG. 9A) subject to PR coating may be disposed on the spin-chuck 400. The spin-chuck 400 include a vacuum hole therein, and fix the wafer W through vacuum suction. Furthermore, when PR or thinner is provided to a central portion of the wafer W through the PR dispenser 200, the spin-chuck 400 rotates the wafer W to be coated with the PR or thinner by spreading the PR or thinner on an upper surface of the wafer W. For example, the spin-chuck 400 may rotate the wafer W at a speed of about 1000 rpm to 1600 rpm. Accordingly, the PR or thinner may spread for coating, by a centrifugal force, from the center of the wafer W to an edge thereof.

In the spin coater 1000 of the present embodiment, the PR dispenser 200 may include the nozzles 100 having a double pipe structure and may transfer and eject PR and thinner together. Accordingly, the spin coater 1000 of the present embodiment may very easily perform a reduced resist consumption (RRC) operation, without moving a nozzle and driving a nozzle arm in the PR coating process.

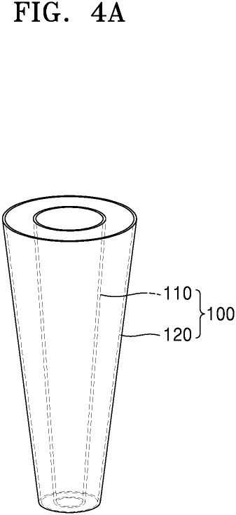

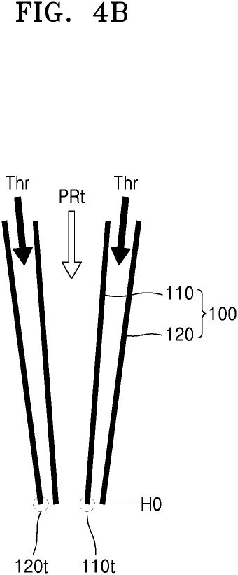

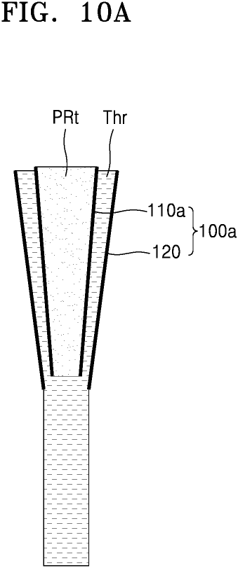

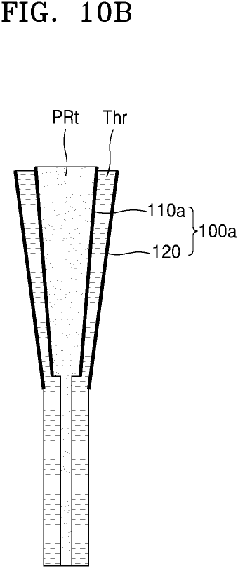

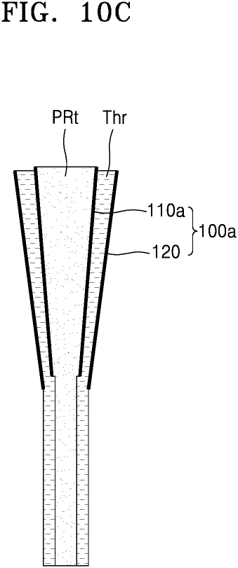

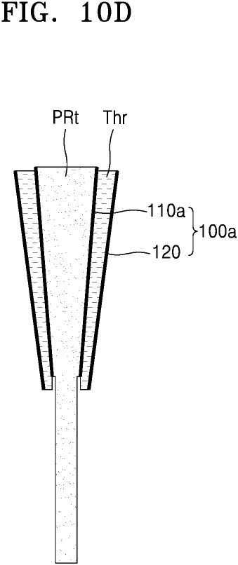

The nozzles 100 having a double pipe structure is described in detail in the following descriptions with reference to FIGS. 4A to 6B, and FIGS. 11A to 12B. Furthermore, in the PR coating process, the RRC operation is described in detail in the following descriptions with reference to FIGS. 9A to 10D.

FIGS. 3A and 3B are a perspective view and a side view, respectively, showing the nozzle housing 300 of the spin coater 1000 of FIG. 1, and the nozzle arm 250 and the nozzles 100 of the PR dispenser of FIG. 2, which are described with reference to FIGS. 1 and 2 together.

Referring to FIGS. 3A and 3B, the nozzle arm 250 of the PR dispenser 200 of the present embodiment may include the support block 252, the pipe block 254, and the nozzle block 256. The nozzles 100 may be coupled to the nozzle block 256. Different types of PRs may be transferred and ejected through the nozzles 100. Furthermore, each of the nozzles 100 may have a double pipe structure. Accordingly, each of the nozzles 100 may transfer and eject a corresponding type of PR and thinner together.

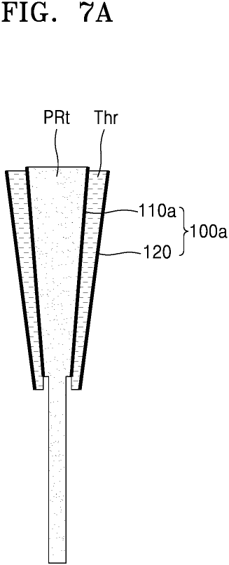

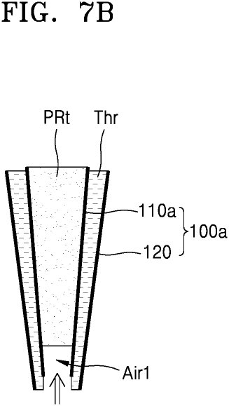

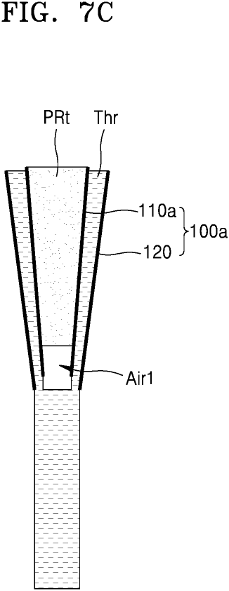

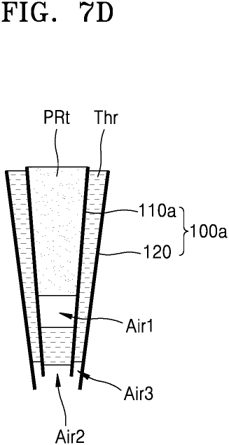

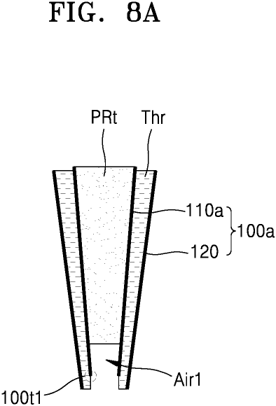

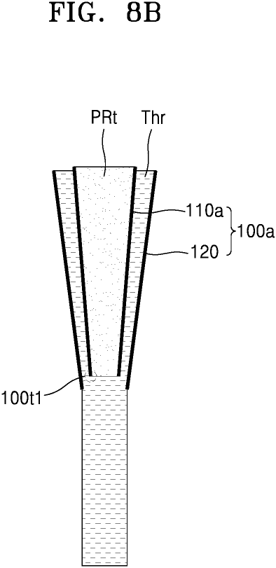

Meanwhile, during idle time, the nozzles 100 may be accommodated and wait in the home spots 320 of the nozzle housing 300. For reference, in an existing spin coater, while the nozzles 100 wait in the home spots 320, a nozzle tip rinsing operation may be performed, and also, a multi-suck-back operation may be performed in the home spots 320. However, in the spin coater 1000 of the present embodiment, as each of the nozzles 100 has a double pipe structure, there is no need to perform the nozzle tip rinsing operation or the multi-suck-back operation in the home spots 320. The multi-suck-back operation is described in detail in the following descriptions with reference to FIGS. 7A to 7D, and the nozzle tip rinsing operation is described in detail in the following descriptions with reference to FIGS. 8A and 8B.

FIGS. 4A and 4B are a perspective view and a cross-sectional view, respectively, showing one of the nozzles 100 of the PR dispenser 200 of FIG. 2.

Referring to FIGS. 4A and 4B, the nozzle 100 of the present embodiment may include an inner pipe 110 and an outer pipe 120. The inner pipe 110 may have a conic pipe shape gradually narrowing downward. As indicated by a white arrow in FIG. 4B, PR PRt may be transferred through the inner pipe 110. Furthermore, the PR PRt may be ejected to the outside through a tip 110t of the inner pipe 110. The inner pipe 110 may be formed of fluorine resin-based resin. For example, the inner pipe 110 may be formed of perfluoroalkoxy (PFA) resin or polytelrafluoro ethylene (PTFE) resin. However, the material of the inner pipe 110 is not limited to the PFA resin or the PTFE resin.

The outer pipe 120 may surround the inner pipe 110 and have a conic pipe shape gradually narrowing downward. As indicated by a black arrow in FIG. 4B, thinner Thr may be transferred through the outer pipe 120. Furthermore, the thinner Thr may be ejected to the outside through a tip 120t of the outer pipe 120. The outer pipe 120 may also be formed of fluorine resin-based resin. For example, the outer pipe 120 may be formed of PFA resin or PTFE resin. However, the material of the outer pipe 120 is not limited to the PFA resin or the PTFE resin.

In the nozzle 100 of the present embodiment, the positions in a vertical direction of the tip 110t of the inner pipe 110 and the tip 120t of the outer pipe 120 may be substantially the same. Here, the vertical direction may be a direction perpendicular to the upper surface of the wafer W subject to PR coating. For example, when the tip 110t of the inner pipe 110 is located at a basic position H0 in the vertical direction, the tip 120t of the outer pipe 120 may also be located at the basic position H0 in the vertical direction. Meanwhile, the nozzle 100 may move up and down in the vertical direction through the nozzle arm 250, and thus, the basic position H0 may also move up and down in the vertical direction.

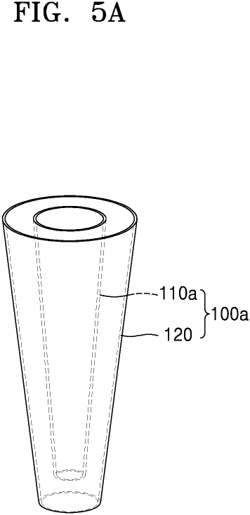

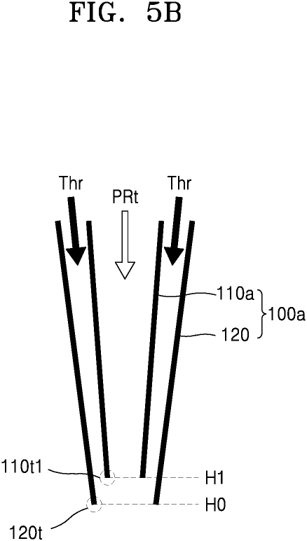

FIG. 5A and FIG. 5B are a perspective views and a cross-sectional views, respectively, showing one of the nozzles 100 of the PR dispenser 200 of FIG. 2, according to some other embodiments. The contents described above with reference to FIGS. 4A and 4B are briefly described or omitted.

Referring to FIGS. 5A and 5B, a nozzle 100a of the present embodiment may be different from the nozzle 100 of FIG. 4A in terms of the structure of an inner pipe 110a. In detail, in the nozzle 100a of the present embodiment, in the vertical direction the position of a tip 110t1 of the inner pipe 110a and the position of the tip 120t of the outer pipe 120 may be different from each other. For example, in the vertical direction, the tip 110t1 of the inner pipe 110a may have a first position H1, and the tip 120t of the outer pipe 120 may have the position of the basic position H0. The first position H1 may be higher than the basic position H0.

The nozzle 100a may have a structure in which the tip 120t of the outer pipe 120 protrudes further than the tip 110t1 of the inner pipe 110a, based on the positions of the tips 110t1 and 120t of the nozzle 100a in the vertical direction. In other words, the tip 110t1 of the inner pipe 110a may have a structure of being recessed inward more than the tip 120t of the outer pipe 120. In the nozzle 100a of the present embodiment, as the tip 110t1 of the inner pipe 110a is disposed inner than the tip 120t of the outer pipe 120, the contact of the tip 110t1 of the inner pipe 110a with air may be reduced. Accordingly, contamination of the tip 110t1 of the inner pipe 110a may be reduced.

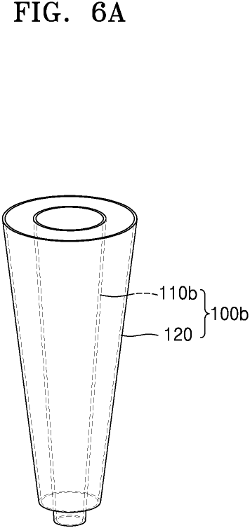

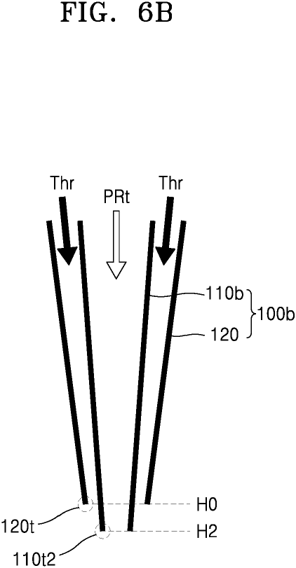

Referring to FIGS. 6A and 6B, a nozzle 100b of the present embodiment may be different from the nozzle 100 of FIG. 4A in terms of the structure of the inner pipe 110b. In detail, in the nozzle 100b of the present embodiment, in the vertical direction, the position of a tip 110t2 of the inner pipe 110b and the position of the tip 120t of the outer pipe 120 may be different from each other. For example, in the vertical direction, the tip 110t2 of the inner pipe 110b may have a second position H2, and the tip 120t of the outer pipe 120 may have the position of the basic position H0. The second position H2 may be lower than the basic position H0.

The nozzle 100b may have a structure in which the tip 110t2 of the inner pipe 110b protrudes further than the tip 120t of the outer pipe 120, based on the positions of the tips 110t2 and 120t of the nozzle 100b in the vertical direction. In the nozzle 100b of the present embodiment, as the tip 110t2 of the inner pipe 110b protrudes further than the tip 120t of the outer pipe 120, the PR PRt in the inner pipe 110b may be prevented from being mixed with the thinner Thr in the outer pipe 120.

FIGS. 7A to 7D are conceptual views showing a multi-suck-back operation using the nozzle 100a of FIG. 5A. For reference, the multi-suck-back operation may mean a technology to suck-back thinner more than one time into a tip portion of a nozzle in which PR is transferred, to prevent curing of the PR.

Referring to FIG. 7A, first, the nozzle 100a ejects only the PR PRt. Here, the ejection of only the PR PRt is included in a process of coating the PR PRt on the upper surface of the wafer W, and also, may correspond to a final operation of PR dispensing in the PR PRt coating process. As illustrated in FIG. 7A, in the ejection of only the PR PRt, the thinner Thr may not be ejected.

Referring to FIG. 7B, next, the PR PRt is primarily sucked-back in the inner pipe 110a. Here, the suck-back operation may mean that, as indicated by an arrow, a fluid is sucked backward in a direction opposite to an ejection direction. The suck-back operation may be performed for a very short time. For example, the suck-back operation may be performed for a very short time of about several to tens of microseconds. In the primary suck-back operation, air Air1 is sucked together so that the air Air1 may be maintained in the inside adjacent to the tip of the inner pipe 110a.

Referring to FIG. 7C, next, the thinner Thr is ejected through the outer pipe 120. In the thinner ejection operation, the air Air1 may be maintained in the inside adjacent to the tip of the inner pipe 110a. The thinner ejection operation may include a function of rinsing the tip of the inner pipe 110a.

Referring to FIG. 7D, next, the PR PRt is secondarily sucked-back in the inner pipe 110a. The thinner Thr may be rapidly sucked into the inside adjacent to the tip of the inner pipe 110a through the secondary suck-back operation. Furthermore, the existing air Air1 may be moved upward. Accordingly, after the secondary suck-back operation, the thinner Thr, the air Air1, and the PR PRt may be disposed in the inside of the inner pipe 110a sequentially from the bottom thereof.

Furthermore, in the secondary suck-back operation, as the ejection of the thinner Thr is stopped, according to an embodiment, in the secondary suck-back operation, air may be sucked into the inner pipe 110a. In this case, after the secondary suck-back operation, air Air2, the thinner Thr, the air Air1, and the PR PRt may be disposed in the inner pipe 110a sequentially from the bottom thereof.

Meanwhile, after the secondary suck-back operation, the thinner Thr is thirdly sucked-back in the outer pipe 120. The thinner Thr may be sucked into the inside adjacent to the tip of the outer pipe 120 through the tertiary suck-back operation. Accordingly, after the tertiary suck-back operation, air Air3 and the thinner Thr may be disposed in the outer pipe 120 sequentially from the bottom thereof. The tertiary suck-back operation may be performed for a very short time, for example, several microseconds or less. For reference, the primary to tertiary suck-back operations together are referred to as a multi-suck-back operation.

The nozzle 100a of the present embodiment has a double pipe structure, and may transfer and eject the PR PRt and the thinner Thr together. Accordingly, when performing a multi-suck-back operation, there is no need to move the nozzle 100a, and thus, there is no need to drive the nozzle arm 250. Accordingly, the nozzle 100a of the present embodiment may perform the multi-suck-back operation very easily and simply.

For reference, for an existing nozzle, a PR nozzle for transferring and ejecting PR and a thinner nozzle for transferring and ejecting thinner are different from each other, and thus, the multi-suck-back operation may be performed by using the thinner in home spots after moving the PR nozzle to the home spots. Accordingly, it is unavoidable to move the PR nozzle and drive the nozzle arm. Furthermore, in the multi-suck-back operation, as cleaning home spots and rinsing PR nozzle tips are performed together, the multi-suck-back operation may be very complicated. In contrast, the nozzle 100a of the present embodiment having a double pipe structure may perform the multi-suck-back operation very easily and simply, without moving the nozzle 100a and without driving the nozzle arm 250.

For reference, in the rinsing operation and the multi-suck-back operation in the existing nozzle, the PR nozzle having completed PR dispensing is moved to the home spots, and after performing the subsequent PR dispensing in the home spots, a primarily suck-back is performed. Next, the home spots are cleaned by providing thinner in the home spots. Next, a PR nozzle tip rinsing operation is performed with the thinner in the home spots. Next, a secondary suck-back operation of sucking the thinner in the home spots is performed. Finally, a tertiary suck-back of sucking air from the outside of the home spots is performed.

FIGS. 8A and 8B are conceptual views showing a tip rinsing operation in the nozzle 100a of FIG. 5A.

Referring to FIG. 8A, the nozzle 100a of the present embodiment may maintain the primary suck-back state of FIG. 7B in the preceding multi-suck-back operation. In other words, after the ejection of only the PR PRt, the air Air1 may be maintained in the inside adjacent to the tip 110t1 of the inner pipe 110a through the primary suck-back operation. Meanwhile, according to an embodiment, the nozzle 100a may maintain the tertiary suck-back state of FIG. 7D.

Referring to FIG. 8B, in the primary suck-back state or tertiary suck-back state, the thinner Thr is ejected through the outer pipe 120. The operation of rinsing the tip 110t1 of the inner pipe 110a may be performed through the ejection of the thinner Thr. In FIG. 8B, in the thinner ejection operation, the PR PRt is somewhat moved downward so that the air Air1 may be removed. However, according to an embodiment, the air Air1 may be maintained without change in the inside adjacent to the tip 110t1 of the inner pipe 110a. In addition, in the nozzle 100a of the present embodiment, as described above, as the tip 110t1 of the inner pipe 110a is disposed inner than the tip 120t of the outer pipe 120, the contact of the tip 110t1 of the inner pipe 110a with air may be reduced. Accordingly, the contamination of the tip 110t1 of the inner pipe 110a may be reduced.

FIGS. 9A to 9E are conceptual views showing a process of coating PR by using the spin coater 1000 of FIG. 1. The PR dispenser 200 of the spin coater 1000 of FIG. 1 may employ the nozzle 100a of FIG. 5A. Accordingly, the following descriptions are presented with reference to FIGS. 5A and 5B together.

Referring to FIG. 9A, in a process of coating PR by using the spin coater 1000 of the present embodiment, first, the thinner Thr is dispensed onto the wafer W on the spin-chuck 400 by using the nozzle 100a. The dispensing of the thinner Thr may be made, as illustrated in FIG. 9A, by ejecting the thinner Thr onto the central portion of the wafer W, by using the outer pipe 120 of the nozzle 100a.

Referring to FIG. 9B, after the dispensing of the thinner Thr, the thinner Thr spreads toward the outer portion of the wafer W. The spreading of the thinner Thr may be made, as indicated by black arrows, by a centrifugal force through the rotation of the spin-chuck 400. Here, the thinner Thr is a kind of solvent having hydrophobicity, and may reinforce the hydrophobicity of the wafer W. Accordingly, by reinforcing the hydrophobicity of the wafer W through the thinner Thr, in the subsequent PR coating process, the spreading of PR may be facilitated, and thus, the PR coating process may be performed with a small amount of PR. Generally, the thinner dispensing and spreading operation is referred to as a pre-wet process.

Referring to FIG. 9C, after the spreading of the thinner Thr, the PR PRt is dispensed onto the wafer W on the spin-chuck 400 by using the nozzle 100a. The dispensing of the PR PRt, as illustrated in FIG. 9C, may be made by ejecting the PR PRt onto the central portion of the wafer W, by using the inner pipe 110a of the nozzle 100a. Next, the PR PRt spreads toward the outer portion of the wafer W. The spreading of the PR PRt may also be made by a centrifugal force through the rotation of the spin-chuck 400.

Referring to FIG. 9D, after the spreading of the PR PRt, the PR PRt is reflowed. The reflow of the PR PRt may mean an operation of reducing the rotation speed of the spin-chuck 400 to a low speed to make the PR PRt flow naturally. The reflow of the PR PRt may be performed to prevent irregular coating of the PR PRt as the PR PRt flows excessively toward the outer portion in the spreading of the PR PRt due to the high-speed rotation of the spin-chuck 400. As the PR PRt flows naturally on the wafer W through the reflow of the PR PRt, the PR PRt may be uniformly coated on the whole of the wafer W. In FIG. 9D, PR PRc with a different hatching at the center may mean that, through the reflow of the PR PRt, the PR PRt gathers again in the central portion that has become thin.

Referring to FIG. 9E, after the reflow of the PR PRt, casting is performed on the PR PRt. The casting on the PR PRt may mean an operation of uniformly rotating, after the reflow, the spin-chuck 400 to a certain high speed to vaporize the thinner Thr. Through the casting on the PR PRt, the PR PRt is hardened on the wafer W, and the PR coating process on the wafer W may be completed.

Meanwhile, among the PR coating process, the processes of FIGS. 9A to 9C are previously referred to as the RRC operation. As the meaning of the term, the consumption of the PR PRt may be reduced in the PR coating process, through the RRC operation. In detail, before the ejection and spreading of the PR PRt, first, the hydrophobicity of the wafer W is reinforced by ejecting and spreading the thinner Thr, and then, by performing the ejection and spreading of the PR PRt, the use of the PR PRt may be reduced.

In the PR coating process using the spin coater 1000 of the present embodiment, by using the nozzle 100a having a double pipe structure, the thinner Thr and the PR PRt may be ejected together through one nozzle 100a. Accordingly, there is no need to replace a nozzle in the pre-wet process of the thinner Thr and the ejection operation of the PR PRt. In other words, as the spin coater 1000 of the present embodiment uses the nozzle 100a having a double pipe structure, there is no need to change or move nozzles in the PR coating process including the pre-wet process, and thus, the driving of the nozzle arm 250 is unnecessary. As a result, the spin coater 1000 of the present embodiment may very easily perform the PR coating process including the pre-wet process by using one nozzle 100a.

FIGS. 10A to 10D are conceptual views showing the RRC operation using the nozzle 100a of FIG. 5A in the process of coating the PR PRt using the spin coater 1000 of FIG. 1, which may correspond to the processes of FIGS. 9A to 9C.

Referring to FIG. 10A, in the RRC operation of the process of coating the PR PRt using the spin coater 1000 of the present embodiment, first, the thinner Thr is ejected onto the wafer W by using the nozzle 100a. The ejection of the thinner Thr, as illustrated in FIG. 10A, may be performed by using the outer pipe 120 of the nozzle 100a. During the thinner ejection operation, the PR PRt may not be ejected and may be maintained in the inner pipe 110a. Meanwhile, the thinner ejection operation may correspond to the thinner dispensing and spreading operation of FIGS. 9A and 9B described above.

Referring to FIG. 10B, after the ejection of the thinner Thr only, the PR PRt is ejected through the inner pipe 110a of the nozzle 100a, and the thinner Thr is continuously ejected through the outer pipe 120. In this process, as the PR PRt is mixed with the thinner Thr, the PR PRt and the thinner Thr may be simultaneously ejected.

Referring to FIG. 10C, next, the flow rate of the thinner Thr gradually decreases, and the flow rate of the PR PRt gradually increases. In comparison between FIG. 10C with FIG. 10B, it may be checked that, while the width of the PR PRt ejected through the inner pipe 110a of the nozzle 100a increases, the width of the thinner Thr ejected through the outer pipe 120 decreases. As, in FIGS. 10B and 10C, the flow rate of the thinner Thr gradually decreases and the flow rate of the PR PRt gradually increases, the operation of simultaneously ejecting the PR PRt and the thinner Thr may correspond to the pre-wet process of the thinner Thr and the dispensing and spreading operation of the PR PRt of FIGS. 9A to 9C.

Referring to FIG. 10D, next, the ejection of the thinner Thr is stopped, and only the PR PRt is ejected through the inner pipe 110a of the nozzles 100. The operation of ejecting the PR PRt only may correspond to the dispensing and spreading operation of the PR PRt of FIG. 9C.

For reference, as described above, the RRC operation starts in the nozzle 100a in a multi-suck-back state, it is not that the RRC operation is instantly performed, but that an operation of disposing a certain amount of the thinner Thr and the PR PRt by pre-dispending the same may precede. By removing portions of the thinner Thr and the PR PRt contacting air through a pre-dispensing operation, the PR coating process may be performed with the thinner Thr and the PR PRt in an optimal state.

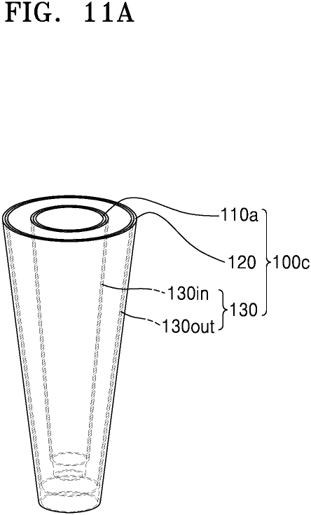

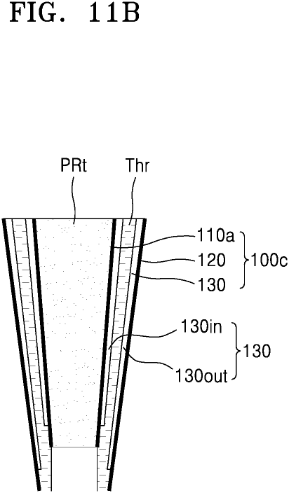

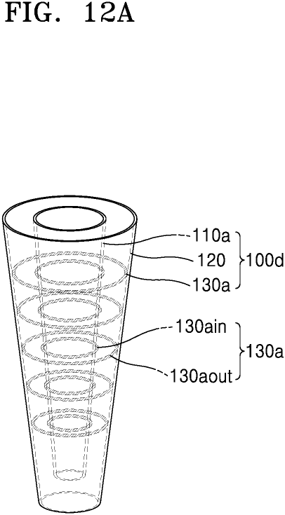

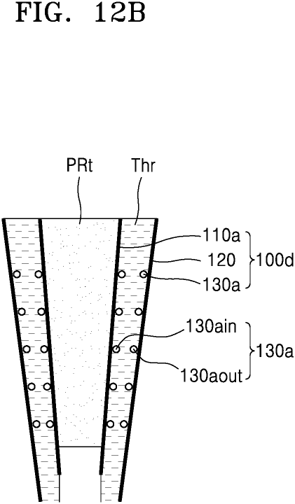

FIGS. 11A to 12B are a perspective views and a cross-sectional views, respectively, showing the nozzle employed in the PR dispenser 200 of FIG. 2, according to some other embodiments. The contents described above with reference to FIGS. 4A to 6B are briefly described or omitted.

Referring to FIGS. 11A and 11B, a nozzle 100c of the present embodiment may be different from the nozzle 100a of FIG. 4A in terms of further including a conductive layer 130. In detail, the nozzle 100c of the present embodiment, similarly to the nozzle 100a of FIG. 4A, may include the inner pipe 110a and the outer pipe 120. Furthermore, the nozzle 100c of the present embodiment may further include the conductive layer 130 in the outer pipe 120.

The conductive layer 130 may include an inner conductive layer 130inon an inner wall of an inner side of the outer pipe 120 and an outer conductive layer 130outon an inner wall of an outer side of the outer pipe 120. Here, the inner wall of the inner side of the outer pipe 120 may correspond to an outer side wall of the inner pipe 110a. Accordingly, the inner conductive layer 130in, similarly to the inner pipe 110a, may have a conic pipe shape gradually narrowing downward. Furthermore, the outer conductive layer 130out, similarly to the outer pipe 120, may have a conic pipe shape gradually narrowing downward. As can be seen in FIG. 11B, the conductive layer 130 may not be formed in the tip portion of the outer pipe 120 or the inner pipe 110a. However, according to an embodiment, the conductive layer 130 may be formed in the tip portion of the outer pipe 120 or the inner pipe 110a.

The conductive layer 130 prevents the inner pipe 110a and the outer pipe 120 from being charged, and thus, the transferring and ejection of the thinner Thr and the PR PRt may be facilitated. The conductive layer 130 may be formed of a metal and the like. However, the material of the conductive layer 130 is not limited to the metal. For example, the conductive layer 130 may be formed of a non-metal material such as carbon and the like. Meanwhile, for an antistatic function, the conductive layer 130 may be connected to ground power. For example, the ground power may be connected to the conductive layer 130 of the nozzle 100a via the nozzle arm 250. In addition, according to an embodiment, a conductive layer may be disposed on an inner side wall of the inner pipe 110a.

Referring to FIGS. 12A and 12B, a nozzle 100d of the present embodiment is similar to the nozzle 100c of FIG. 11A in terms of further including a conductive layer 130a, but may be different from the nozzle 100c of FIG. 11A in terms of the structure of the conductive layer 130a. In detail, the nozzle 100d of the present embodiment, similarly to the nozzle 100c of FIG. 11A, may include the inner pipe 110a, the outer pipe 120, and the conductive layer 130a.

The conductive layer 130a may have a shape of a plurality of conductive ring pairs. Each of the conductive ring pairs of the conductive layer 130a may include an inner conductive ring 130ain surrounding the inner wall of the inner side of the outer pipe 120 or an outer side wall of the inner pipe 110a, and an outer conductive ring 130aout surrounding the inner wall of the outer side of the outer pipe 120. As can be seen in FIG. 12B, the conductive ring pairs of the conductive layer 130a may not be formed in the tip portion of the outer pipe 120 or the inner pipe 110a. However, according to an embodiment, the conductive ring pairs of the conductive layer 130a may be formed in the tip portion of the outer pipe 120 or the inner pipe 110a.

The conductive layer 130a also prevents the inner pipe 110a and the outer pipe 120 from being charged, and thus, the transferring and ejection of the thinner Thr and the PR PRt may be facilitated. The conductive layer 130a may be formed of a metal or non-metal, and connected to ground power.

It should be understood that embodiments described herein should be considered in a descriptive sense only and not for purposes of limitation. Descriptions of features or aspects within each embodiment should typically be considered as available for other similar features or aspects in other embodiments.

While one or more embodiments have been described with reference to the figures, it will be understood by those of ordinary skill in the art that various changes in form and details may be made therein without departing from the spirit and scope of the disclosure as defined by the following claims.

What is claimed is:

1. A nozzle having a double pipe structure, the nozzle comprising:
an inner pipe having a conical shape gradually narrowing downward, through which photoresist (PR) is transferred, and having a tip through which the PR is ejected; and
an outer pipe surrounding the inner pipe, having a conical shape gradually narrowing downward, through which thinner is transferred, and having a tip through which the thinner is ejected,
wherein the nozzle is coupled to a nozzle arm and moved, and multi-suck-back is performed without driving the nozzle arm.

2. The nozzle of claim 1, wherein the tip of the inner pipe protrudes downward from the tip of the outer pipe.

3. The nozzle of claim 1, wherein the tip of the outer pipe protrudes downward from the tip of the inner pipe.

4. The nozzle of claim 1, wherein an antistatic conductive layer is disposed on the outer pipe, and the conductive layer is connected to ground.

5. The nozzle of claim 4, wherein the conductive layer is disposed entirely on an inner wall of an inner side and an inner wall of an outer side of the outer pipe.

6. The nozzle of claim 4, wherein the conductive layer comprises at least one conductive ring pair, the at least one conductive ring pair comprising a first conductive ring surrounding an inner wall of an inner side of the outer pipe and a second conductive ring surrounding an inner wall of an outer side of the outer pipe.

7. The nozzle of claim 1, wherein air, thinner, air, and the PR are sequentially disposed upward in the inner pipe through the multi-suck-back, and air and thinner are sequentially disposed upward in the outer pipe.

8. The nozzle of claim 1, wherein, without moving the nozzle, an operation of rinsing a tip of the inner pipe is automatically performed through an operation of ejecting the thinner from the outer pipe.

9. The nozzle of claim 1, wherein a reduced resist consumption (RRC) operation, in which the thinner is ejected onto a wafer and spread and then the PR is ejected and spread, is performed by using the nozzle, without moving the nozzle.

10. A photoresist (PR) dispenser comprising:
a nozzle having a double pipe structure; and
a nozzle arm moving the nozzle,
wherein the nozzle comprises: an inner pipe having a conical shape gradually narrowing downward, through which PR is transferred, and having a tip through which the PR is ejected; and an outer pipe surrounding the inner pipe, having a conical shape gradually narrowing downward, through which thinner is transferred, and having a tip through which the thinner is ejected, and
wherein multi-suck-back is performed in the nozzle without driving the nozzle arm.

11. The PR dispenser of claim 10, wherein the tip of the inner pipe protrudes downward from the tip of the outer pipe, or the tip of the outer pipe protrudes downward from the tip of the inner pipe.

12. The PR dispenser of claim 10, wherein an antistatic conductive layer is disposed on the outer pipe, and the conductive layer is connected to ground.

13. The PR dispenser of claim 10, wherein air, the thinner, air, and the PR are sequentially disposed upward in the inner pipe through the multi-suck-back, and air and the thinner are sequentially disposed upward in the outer pipe.

14. The PR dispenser of claim 10, wherein there is no movement of the nozzle in a reduced resist consumption (RRC) operation and an operation of rinsing a tip of the nozzle.

15. The PR dispenser of claim 10, wherein the nozzle arm comprises a nozzle block to which at least one nozzle is coupled and a pipe block to which the nozzle block is coupled, and in which intermediate pipes through which the PR and the thinner are transferred to the nozzle are disposed.

16. A spin coater comprising:
a nozzle having a double pipe structure;
a nozzle arm moving the nozzle;
a transfer device moving the nozzle arm in one direction; and
at least one spinner on which a wafer subject to coating is disposed, the at least one spinner rotating the wafer,
wherein the nozzle comprises: an inner pipe having a conical shape gradually narrowing downward, through which photoresist (PR) is transferred, and having a tip through which the PR is ejected; and an outer pipe surrounding the inner pipe, having a conical shape gradually narrowing downward, through which thinner is transferred, and having a tip through which the thinner is ejected, and
wherein multi-suck-back is performed in the nozzle without driving the nozzle arm.

17. The spin coater of claim 16, wherein the tip of the inner pipe protrudes downward from the tip of the outer pipe, or the tip of the outer pipe protrudes downward from the tip of the inner pipe.

18. The spin coater of claim 16, wherein an antistatic conductive layer is disposed on the outer pipe, and the conductive layer is connected to ground.

19. The spin coater of claim 16, wherein there is no movement of the nozzle in a reduced resist consumption (RRC) operation and an operation of rinsing a tip of the nozzle.

20. The spin coater of claim 16, wherein the spinner includes a plurality of spinners,
the nozzle arm is moved to the spinner corresponding thereto through the transfer device, and
PR coating is performed on the wafer corresponding thereto through a reduced resist consumption (RRC) operation without moving the nozzle.
